(19) United States
(12) Patent Application Publication
(10) Pub. No.: US 2003/0203284 A1
(43) Pub. Date: Oct. 30, 2003

(54) Method for forming micropore, method for manufacturing semiconductor device, semiconductor device, display unit, and electronic device

(75) Inventors: Chiharu Iriguchi, Fujimi-machi (JP); Mitsutoshi Miyasaka, Suwa (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/395,147

(22) Filed: Mar. 25, 2003

(30) Foreign Application Priority Data
Mar. 29, 2002 (JP) 2002-93430

(51) Int. Cl. G03H 1/04; G03H 1/10; G03F 7/40; G03F 7/16; H01L 29/04; H01L 31/036; H01L 29/76; H01L 31/112; H01L 27/148; H01L 21/00; H01L 21/84

(52) U.S. Cl. 430/1; 430/314; 430/319; 257/66; 257/235; 438/149

(57) ABSTRACT

The invention forms micropores by an off-axis holographic exposure process. A method of forming micropores in a substrate includes: forming a photosensitive material layer on a substrate using a photosensitive material; applying a reconstruction beam on a holographic mask, which has a pattern that is formed by an off-axis holographic exposure process and has high resolution in a predetermined direction, to allow the holographic mask to emit a first diffracted beam, and then exposing the photosensitive material layer to the first diffracted beam; causing the holographic mask to rotate at a predetermined angle with respect to the substrate or causing the substrate to rotate at a predetermined angle with respect to the holographic mask, applying the reconstruction beam to the holographic mask to emit a second diffracted beam, and then exposing the photosensitive material layer to the second diffracted beam; removing unnecessary portions from the photosensitive material layer by developing the photosensitive material layer; and forming micropores in the substrate by etching the substrate using the resulting photosensitive material layer on the substrate.

### BACKGROUND OF THE INVENTION

1. Field of Invention

The present invention relates to an exposure process in which a holographic technique is used. The invention particularly relates to a method of forming micropores by an off-axis exposure process by which a pattern having high resolution can be formed using diagonally applied light.

2. Description of Related Art

Related art methods of patterning semiconductor devices include an exposure process in which a holographic technique is used. This exposure process includes the following two steps: a recording step of forming a desired pattern on a holographic mask, and an exposing step of irradiating the resulting holographic mask with a reconstruction beam to expose a photoresist coating to form a pattern on a semiconductor substrate for semiconductor devices.

In the recording step of the holographic mask, a laser beam is applied to an original reticle having a mask pattern corresponding to a pattern for semiconductor devices to generate a diffracted beam. This diffracted beam reaches the recording surface of the holographic mask. On the other hand, a reference beam is applied on the reverse side of the recording surface at an angle of 45°. This reference beam causes interference with the diffracted beam transmitted from the original reticle to expose the recording surface, thereby recording another pattern on the recording surface according to the interference pattern. In the exposing step of the photoresist coating, the holographic mask is placed at a position corresponding to the original reticle and the reconstruction beam is then applied to the holographic mask in a direction that is opposite to that of the recording step. The diffracted beam forms an image that agrees with the original pattern on the photoresist coating. The holographic technique has the following advantages: high resolution can be achieved because there are no aberrations in principle, and the same pattern as that of the original reticle can be obtained because all the amplitude and phase information in a scattered light can be recorded.

The related art also includes a new holographic recording process, which is an exposure process in which a pattern can be recorded at higher resolution. This exposure process has been developed by Holtronic Technologies SA in Switzerland. In this exposure process, a beam of light is diagonally applied to a holographic mask in the recording step to record a high-resolution pattern on the holographic mask in a direction along the axis of perspective of the optical axis of the beam applied to the holographic mask. Furthermore, another pattern can be recorded on the holographic mask at conventional resolution in the direction perpendicular to the axis of perspective. According to this technique, 125-nm line resolution can be achieved using a beam of exposure light having a wavelength of 364 nm. This technique is disclosed in M. Barge, S. Bruynooghe, F. Clube, A. Nobari, J. L. Saussol, E. Grass, H. M. Barge, S. Bruynooghe, F. Clube, A. Nobari, J. L. Saussol, E. Grass, H. Mayer, B. Schanabel, and E. B. Kl, “120-nm lithography using off-axis TIR holography and 364-nm exposure wavelength”, Microelectronic Engineering, Vol. 57-58 (2001), pp. 59-63.

In the off-axis holographic exposure process, high resolution can be achieved. However, such high resolution is obtained only in one direction, and therefore such a process is not suitable for the high-resolution recording of an arbitrary pattern.

### SUMMARY OF THE INVENTION

The related art includes nano-technology, and therefore many microprocessing techniques can be used. Since an off-axis holographic exposure technique can provide a high-resolution pattern, it is industrially advantageous to provide a method of processing micropores using this exposure technique.

Among methods of manufacturing high-performance thin-film transistors, a method of manufacturing thin-film transistors by processing micropores can be used. This method includes: forming micropores in an insulating layer on a substrate; forming an amorphous silicon layer on the resulting insulating layer; applying a laser beam on the amorphous silicon layer to cause part of the amorphous silicon layer to melt while other portions of the amorphous silicon layer in the micropores remain unmelted; and allowing the unmelted amorphous silicon layer portions, functioning as crystalline nuclei, to grow to form substantially single-crystalline silicon sub-layers in the molten amorphous silicon layer, the substantially single-crystalline silicon sub-layers being each disposed on the corresponding micropores. This technique is disclosed in detail in the following publications: “Single Crystal Thin Film Transistors”, IBM TECHNICAL DISCLOSURE BULLETIN, August 1993, pp. 257-258; “Advanced Excimer-laser Crystallization Techniques of Si Thin-film for Location Control of Large Grain on Glass”, R. Ishihara, et al., Proc. SPIE, 2001, Vol. 4295, pp. 14-23; and Japanese Unexamined Patent Application Publication No. 62-119914. In this technique, the micropore size must be sufficiently small in order to prevent a plurality of crystalline nuclei from growing in one micropore.

The inventors have devised a method of forming micropores to form the above thin-film transistors using an off-axis holographic exposure technique. The present invention provides a method of forming micropores to form the above thin-film transistors using such an off-axis holographic exposure technique.

The present invention provides a method of manufacturing a high-performance semiconductor device using the off-axis holographic exposure technique.

Furthermore, the present invention provides a display unit and an electronic device including such a high-performance semiconductor device manufactured using the off-axis holographic exposure technique.

In order to address or solve the above and/or other problems, the present invention provides a method of forming micropores in a substrate including: forming a photosensitive material layer on a substrate using a photosensitive material; applying a reconstruction beam on a holographic mask, which has a pattern that is formed by an off-axis holographic exposure process and has high resolution in a predetermined direction, to allow the holographic mask to emit a first diffracted beam, and then exposing the photosensitive material layer to the first diffracted beam; causing the holographic mask to rotate at a predetermined angle with respect to the substrate or causing the substrate to rotate at a predetermined angle with respect to the holographic mask, applying the reconstruction beam to the holographic mask to emit a second diffracted beam, and then exposing the photosensitive material layer to the second diffracted beam; removing unnecessary portions from the photosensitive material layer by developing the photosensitive material layer; and forming micropores in the substrate by etching the substrate using the resulting photosensitive material layer on the substrate.

Before applying a reconstruction beam, the substrate and a holographic mask, which has a pattern that is formed by an off-axis holographic exposure process and has high resolution in a predetermined direction, are arranged such that the holographic mask face is parallel to the substrate face and the reference direction of the holographic mask face forms a predetermined angle with respect to the reference direction of the substrate face. After applying a reconstruction beam, the angle formed by the reference direction of the holographic mask face and the reference direction of the substrate face is varied.

In the above method, when a positive photosensitive material is used, the intensity of the first diffracted beam and the intensity of the second diffracted beam are lower than intensity that is sufficient to cause a photochemical reaction in the photosensitive material and the total intensity of the first and second diffracted beams is higher than the intensity that is sufficient to cause a photochemical reaction in the photosensitive material.

In contrast, when a negative photosensitive material is used, the first and second diffracted beams each have intensity that is sufficient to cause a photochemical reaction in the photosensitive material.

Furthermore, when the positive photosensitive material is used, the method may further include exposing a region of the substrate to a beam, the region being used to form the micropores. When a negative photosensitive material is used, the method may further include exposing a region of the substrate, the region not being used to form the micropores. Such procedures are preferably used when the micropores are formed in a desired region of the substrate.

The holographic mask has a pattern formed by an off-axis holographic exposure process by applying a beam on an original reticle having a striped pattern including one or more lines arranged in such a direction that high resolution is obtained when off-axis holographic exposure is performed.

When the positive photosensitive material is used, the holographic mask has a striped pattern having a line width that is substantially equal to the desired diameter of the micropores. When the negative photosensitive material is used, the holographic mask has a striped pattern having a line pitch that is substantially equal to the desired diameter of the micropores.

The present invention provides a method of manufacturing semiconductor devices including: forming micropores in a region of a substrate by a method of forming the micropores, the region being used to form semiconductor devices using a silicon compound; forming an amorphous silicon layer on the substrate having the micropores so as to have a predetermined thickness; transforming the amorphous silicon layer into a polysilicon layer by a solid-phase growth method using heat treatment; applying a laser beam on the amorphous silicon layer to cause part of the amorphous silicon layer to melt while other portions of the amorphous silicon layer in the micropores are allowed to remain unmelted, and then allowing crystalline nuclei, which have formed in the unmelted portions of the amorphous silicon layer in the micropores, to grow to form substantially single-crystalline silicon sub-layers in the amorphous silicon layer, the sub-layers each lying on the corresponding micropores; and forming semiconductor devices including the substantially single-crystalline silicon sublayers functioning as semiconductor sub-layers. Since the regions of the intersections of a grid pattern formed using the striped pattern formed by the off-axis holographic exposure process have a fine size, such regions are suitable to form the micropores used to allow single-crystalline crystals to grow. That is, the line width of the striped pattern formed by the off-axis holographic exposure process is about 100 nm and therefore the micropores having such size are suitable to allow such single-crystalline crystals to grow.

In the above method, the semiconductor devices preferably include parts of the substantially single-crystalline silicon sub-layers except for regions of the substantially single-crystalline silicon sub-layers in the micropores.

In the above method, the micropores preferably have a diameter that is smaller than or equal to that of polysilicon grains formed by the solid-phase growth method using the heat treatment.

In the above method, the substrate preferably has a multilayer structure including a silicon oxide layer and a silicon nitride layer, and the silicon oxide layer is preferably disposed at a position close to the amorphous silicon layer.

The present invention provides a semiconductor device manufactured by the method of forming semiconductor devices, a display unit including the semiconductor device, and an electronic device including the semiconductor device.

The term “substantially single-crystalline silicon” is herein defined as follows: silicon that is single-crystalline or almost single-crystalline.

The display unit is not particularly limited, and includes liquid crystal display elements having liquid crystal layers driven by active matrix addressing and/or electroluminescent elements having electroluminescent layers driven by active matrix addressing, for example.

The electronic device is not particularly limited and includes a mobile phone, a video camera, a personal computer, a head mounted display, a rear or front-type projector, a fax machine having a display function, a finder for digital cameras, a mobile TV, a DSP, a PDA, an electronic notebook, and so on, for example.

### BRIEF DESCRIPTION OF THE DRAWINGS

FIG. 1 is a sectional view illustrating steps of a method of manufacturing micropores according to a first exemplary embodiment;

FIGS. 2(a) and 2(b) are schematics illustrating an off-axis holographic exposure process used in the first embodiment, where FIG. 2(a) is a side elevational view thereof, and FIG. 2(b) is a plan view of an original reticle;

FIGS. 3(a) and 3(b) are plan views showing a pattern formed by exposing a photosensitive material layer in the first exemplary embodiment, where FIG. 3(a) is a plan view showing a pattern formed in a first exposure step, and FIG. 3(b) is a plan view showing another pattern formed in a second exposure step;

FIG. 4 is a plan view showing the photosensitive material layer after a developing step in the first exemplary embodiment;

FIGS. 5(a) and 5(b) are plan views showing a pattern formed by exposing a photosensitive material layer in a second exemplary embodiment, where FIG. 5(a) is a plan view showing a pattern formed in a first exposure step, and FIG. 5(b) is a plan view showing another pattern formed in a second exposure step;

FIG. 6 is a plan view showing a pattern formed by exposing a positive photosensitive material layer in a third exposure step in a third exemplary embodiment;

FIG. 7 is a plan view showing a pattern formed by exposing a negative photosensitive material layer in the third exposure step in the third exemplary embodiment;

FIG. 8 is a plan view showing the photosensitive material layer after a developing step in the third exemplary embodiment;

FIG. 9 is a sectional view showing the first half of steps of a method of manufacturing a semiconductor device according to a fourth exemplary embodiment;

FIG. 10 is a sectional view showing the latter half of the steps of the method of manufacturing the semiconductor device according to the fourth exemplary embodiment;

FIG. 11 is a plan view showing a transistor manufactured by the method of manufacturing a semiconductor device according to the fourth exemplary embodiment;

FIG. 12 is a schematic circuit diagram of a display unit according to a fifth exemplary embodiment;

FIGS. 13(a) and 13(f) are schematics showing exemplary electronic devices according to a fifth exemplary embodiment, where FIG. 13(a) shows a mobile phone, FIG. 13(b) shows a video camera, FIG. 13(c) shows a mobile personal computer, FIG. 13(d) shows a head-mounted display, FIG. 13(e) shows a rear-type projector, and FIG. 13(f) shows a front-type projector, where the electronic devices include a display unit of the present invention.

### DETAILED DESCRIPTION OF PREFERRED EMBODIMENTS

The present invention is further illustrated with reference to the accompanying drawings.

<First Exemplary Embodiment>

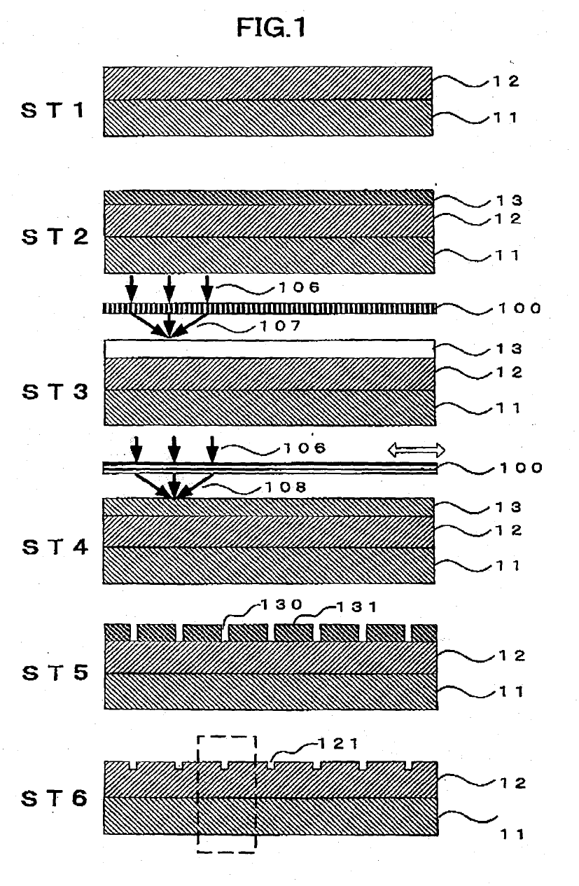

A first exemplary embodiment provides a method of manufacturing micropores using a positive photosensitive material. In this exemplary embodiment, the micropores are formed on an entire surface of a substrate. The manufacturing method of the micropores of this exemplary embodiment is described below with reference to FIG. 1, which is a sectional view showing manufacturing steps.

Step of Forming Silicon Compound Layer (ST1)

A layer including a material suitable to process pores is formed on a substrate. The material is not particularly limited and can be determined depending on the industrial uses. In this exemplary embodiment, a silicon compound layer, which is readily processed, is formed. The silicon compound layer 12 is formed on a glass substrate 11 by the deposition of silicon oxide. Various methods of forming a silicon oxide layer on a substrate are known and include a chemical vapor deposition method, such as a plasma chemical vapor deposition (PECVD) method, a low-pressure chemical vapor deposition (LPCVD) method, and a sputtering method. For example, the silicon compound layer 12 having a thickness of 1 μm is formed by the PECVD method.

Step of Forming Photosensitive Material Layer (ST2)

A positive photosensitive material layer 13 is subsequently formed on the silicon compound layer 12 using a positive photosensitive material. This positive photosensitive material includes a known photoresist resin, such as a novolac resin, a polymethyl methacrylate resin, a PMMA-polymethyl isopropenyl ketone resin, and a PMIPK resin; and inorganic photoresist materials such as Se—Ge compounds, where the above resins contain a benzoic sensitizing agent and are decomposed into alkali-soluble compounds when such resins are irradiated with UV rays. The photosensitive material layer 13 can be formed by a known method, such as a painting method and a sputtering method. In order to clean and homogenize the substrate surface, adsorbed moisture may be removed from the surface in a pretreatment step before the photosensitive material layer 13 is formed. The positive photosensitive material layer 13 has a thickness that is suitable for a holographic exposure process, and the thickness is 0.3 to 1.0 μm and preferably 0.5 μm or less. Pre-baking may be performed depending on the properties of the photosensitive material in order to vaporize a solvent to strongly join the positive photosensitive material layer 13 to the silicon compound layer 12, thereby increasing the efficiency of a photochemical reaction caused by exposure.

Step of Arranging Holographic Mask (ST3)

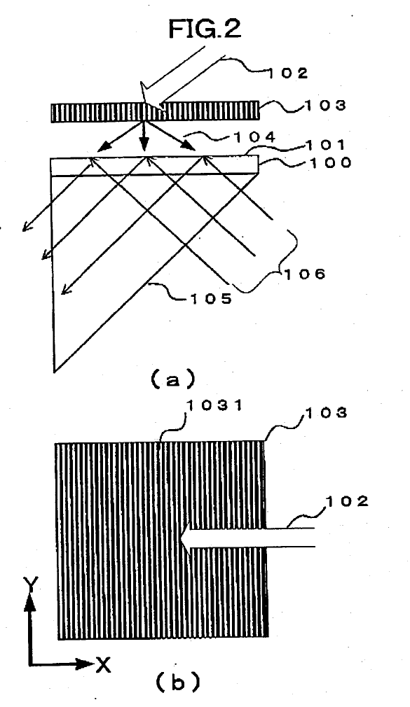

A method of forming a holographic mask according to the present invention is shown in FIGS. 2(a) and 2(b). FIG. 2(a) is a side elevational view showing the holographic mask in the recording step, and FIG. 2(b) is plan view showing the holographic mask.

In general, in a holographic exposure process, a holographic exposure system is used to record a pattern on the holographic mask. The holographic mask is placed at a position away at a predetermined distance from an original reticle having a mask pattern, which corresponds to a pattern to be finally formed. An object laser beam (a laser beam for irradiation) is then applied to the upper surface of the original reticle and a reference beam is applied to the lower surface of the holographic mask at an angle of 45°. The object beam is diffracted by the mask pattern on the original reticle and the diffracted beam reaches the holographic mask. The diffracted beam causes interference with the reference beam, which is applied to the lower surface of the holographic mask, to form interference fringes, which are recorded on the holographic mask to form an exposure pattern. The original reticle is raster-scanned with the object beam and the reference beam, thereby recording the pattern over the scanned surface. For example, an argon ion laser system is used for the source of the laser beam.

In a reproducing step, the original reticle is replaced with a substrate having a photoresist layer thereon such that the photoresist layer faces the holographic mask, and a reconstruction beam is then applied to the lower surface of the holographic mask in a direction opposite to that of the recording step. As a result, the photoresist layer is exposed and the same pattern as that of the original reticle is formed on the photoresist layer.

In this exemplary embodiment, the holographic mask has a pattern recorded by an off-axis holographic exposure process using the original reticle having a striped pattern including one or more lines arranged in such a direction that high resolution can be obtained when off-axis holographic exposure is performed. As shown in FIG. 2(b), the original reticle 103 has a pattern having high density in a direction (X direction) along the axis of perspective of the optical axis of an object beam 102. Such a high-density pattern corresponds to, for example, a striped pattern 1031. The photoresist layer is patterned using the original reticle to form a positive pattern such that the striped pattern covers regions for forming micropores. The line width of the striped pattern may be varied depending on the use of the micropores. For example, when semiconductor layers are formed by this micropore-processing method using micropores, the line width is slightly smaller than or equal to the diameter of crystal grains that are formed and allowed to grow by the heat treatment of amorphous silicon.

As shown in FIG. 2(a), the object beam 102 is diagonally applied to the upper surface of the original reticle 103 to generate the diffracted beam. A reference beam 106 is applied to the lower surface of the holographic mask 100 to form interference fringes on a holographic recording face 101. In this exemplary embodiment, since the micropores are uniformly formed over the substrate face, the striped pattern 1031 extends over the original reticle 103 in the lateral direction (Y direction) of the original reticle 103. The striped pattern 1031 may be smaller according to needs. The striped pattern 1031 formed by the off-axis holographic exposure process has high resolution and the line width is extremely small, for example, about 120 nm. Such a direction that the lines of the striped pattern 1031 are densely arranged is hereinafter referred to as an X direction. Such a direction that the lines of the striped pattern 1031 extend is hereinafter referred to as a Y direction.

First Exposure Step (ST4)

As shown in the ST3 portion of FIG. 1, before the photoresist layer is exposed, the holographic mask 100 having the striped pattern 1031 recorded by the off-axis holographic exposure process is arranged such that the holographic mask 100 is parallel to the glass substrate 11 and the reference direction of the holographic mask face forms a predetermined angle with respect to the reference direction of the glass substrate face. The striped pattern 1031 that is recorded on the holographic mask 100 and reproduced by the diffracted beam is placed such that the Y direction is perpendicular to the plane of FIG. 1.

The reference beam 106, which is an irradiation beam, is subsequently applied to the holographic mask 100 to allow the holographic mask 100 to emit a first diffracted beam 107, and the photosensitive material layer 13 is then exposed to the first diffracted beam 107. The exposure time is determined depending on the strength of the photosensitive material and the intensity of the first diffracted beam 107.

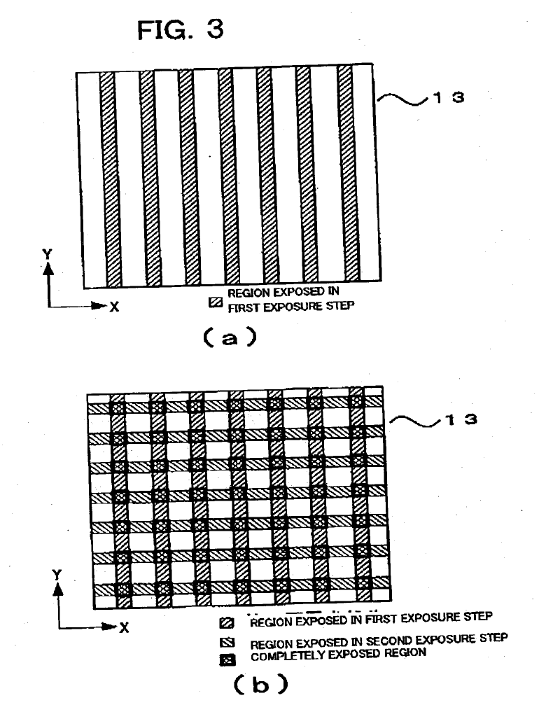

In this exemplary embodiment, the first diffracted beam 107 has intensity smaller than intensity that is sufficient to cause a photochemical reaction in the photosensitive material. That is, the photosensitive material has such sufficient strength that complete exposure is not achieved when the first diffracted beam 107 is used alone. In this first exposure step, incomplete exposure is caused in the photosensitive material. Thereby, the photosensitive material layer 13 has a first striped pattern, as shown in FIG. 3(a).

Second Exposure Step (ST5)

The holographic mask 100 is caused to rotate at a predetermined angle with respect to the glass substrate 11 or the glass substrate 11 is caused to rotate at a predetermined angle with respect to the holographic mask 100 while the holographic mask 100 and the glass substrate 11 remain parallel to each other. The reference beam 106 is applied to the holographic mask 100 again to allow the holographic mask 100 to emit a second diffracted beam 108, and the photosensitive material layer 13 is then exposed to the second diffracted beam 108. Thereby a second striped pattern is formed on the photosensitive material layer 13. That is, the holographic mask 100, the glass substrate 11, or both of them are caused to rotate at a predetermined angle before the second exposure step while the holographic mask 100 and the glass substrate 11 remain parallel to each other, and exposure is then performed such that the lines of the first striped pattern formed in the first exposure step and those of the second striped pattern formed in the second exposure step cross each other at right angles. The exposure time is determined depending on the strength of the photosensitive material and the intensity of the second diffracted beam 108.

The second diffracted beam 108 has an intensity smaller than intensity that is sufficient to cause a photochemical reaction in the photosensitive material when the second diffracted beam 108 is used alone. The total intensity of the first diffracted beam 107 and the second diffracted beam 108 is sufficient to cause the photochemical reaction in the photosensitive material. That is, when the positive photosensitive material layer 13 is irradiated with the first diffracted beam 107 and the second diffracted beam 108, the photochemical reaction is caused in the irradiated regions. Thereby, the irradiated regions become soluble in a specific solvent.

In the second exposure step, the second striped pattern is formed on the photosensitive material layer 13, as shown in FIG. 3(b). In regions irradiated with only the first diffracted beam 107 or the second diffracted beam 108, complete exposure is not achieved. However, in regions irradiated with both the first diffracted beam 107 and the second diffracted beam 108, complete exposure is achieved. The completely exposed regions are the intersections of the lines of the first striped pattern and those of the second striped pattern and have a fine square shape. The side of the square has a length equal to the width of the lines of the first and second striped patterns.

Developing Step (ST6)

The resulting photosensitive material layer 13 is developed to remove unnecessary portions. In this exemplary embodiment, since the photosensitive material is a positive type, a basic aqueous solution is used. Components in the basic aqueous solution reacts with indene carboxylic acid formed from quinone azide in the exposure step and thereby a novolac resin is dissolved in the developing solution.

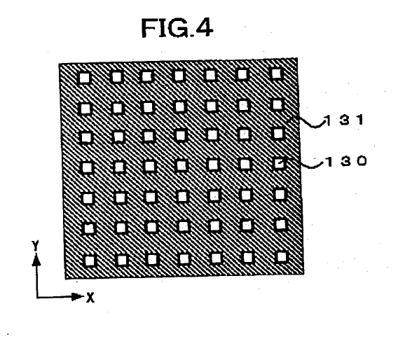

After the development, post-baking may be then performed in order to increase the adhesive strength between the glass substrate 11 and the photosensitive material layer 13 by removing the developing solution and rinse. As shown in FIG. 4, in this developing step, a residual region 131 and windows 130 are formed in the photosensitive material layer 13.

Etching Step (ST7)

The silicon compound layer 12 is etched according to the pattern of the photosensitive material layer 13 on the silicon compound layer 12 to form micropores 121 in the silicon compound layer 12. The following methods can be used in this step: a wet etching method in which a solution is used, and a dry etching method such as a reactive ion etching method or a plasma etching method in which discharge is performed in a gas containing halogen and/or oxygen. The reactive ion etching method, in which anisotropic etching is possible, is preferably used. After the silicon compound layer 12 is etched, the photosensitive material layer 13 remaining on the silicon compound layer 12 is completely removed by the ashing of the photosensitive material layer 13 in oxygen plasma or by the dissolution of the photosensitive material layer 13 in a strong oxidizing solution. The micropores 121 are formed over the silicon compound layer 12 in this etching step. These micropores 121 can be used to form crystal nuclei used to manufacture semiconductor devices, as described in exemplary embodiment 4. The method for forming micropores according to this exemplary embodiment can be used in various industrial fields in which micropores are used.

As described above, according to the first exemplary embodiment, micropores can be formed by an off-axis holographic exposure process using a positive photoresist material. This technique is very important among basic microprocessing techniques in the field of nano-technology.

<Second Exemplary Embodiment>

A second exemplary embodiment provides a method of forming micropores using a negative photosensitive material. In this exemplary embodiment, micropores are formed over a substrate. The micropore-forming method of this exemplary embodiment is similar to that of the first exemplary embodiment except for a resist material used for a photosensitive material layer, an exposure procedure, and a developing procedure. Therefore, in this exemplary embodiment, the same manufacturing steps as those of the first exemplary embodiment are omitted and the manufacturing procedure is described with reference to FIG. 1.

A silicon compound layer-forming step is the same as that (ST1 portion in FIG. 1) of the first exemplary embodiment.

In this exemplary embodiment, in a photosensitive material layer-forming step (ST2 portion in FIG. 1), a photosensitive material layer 13 is formed on a silicon compound layer 12 using a negative photosensitive material instead of a positive photosensitive material. The negative photosensitive material includes known photoresist materials, such as polyvinyl cinnamate resins containing a sensitizing agent, rubber photoresist materials containing isoprene as a main component, polyglycidyl methacrylate, PGMA, WR, polychloromethyl styrene, CMS, phenol resins, MRS, and polystyrene chloride; and inorganic photoresist materials, such as Se—Ge compounds. A method of forming the photosensitive material layer 13, the pretreatment, the thickness, and the pre-baking of the layer are the same as those of the first exemplary embodiment.

A holographic mask-forming step is almost the same as that of the first exemplary embodiment. An original reticle has a negative pattern. That is, the negative pattern provides micropores in regions that are not exposed.

A first exposure step (ST4 portion in FIG. 1) and a second exposure step (ST5 portion in FIG. 1) are almost the same as those of the first exemplary embodiment. A first diffracted beam 107 and a second diffracted beam 108 independently have intensity that is sufficient to cause a photochemical reaction in the photosensitive material. That is, in each of the first and second exposure steps, complete exposure is achieved in irradiated regions.

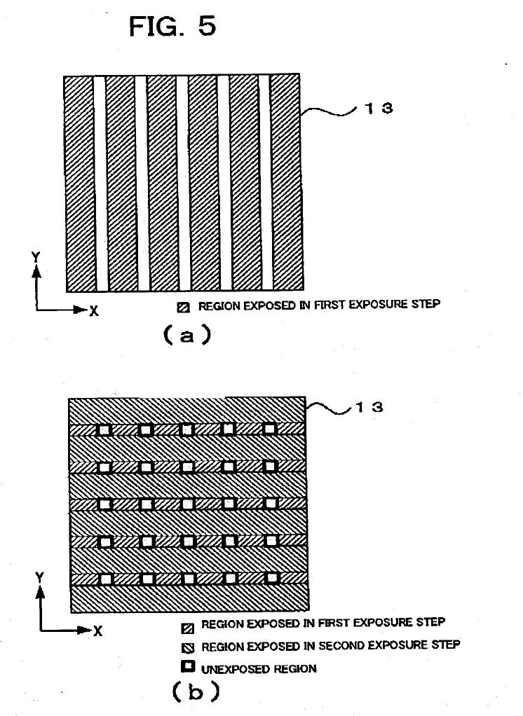

As shown in FIG. 5(a), in the first exposure step, the entire face of the photosensitive material layer 13 except for fine lines is exposed. As shown in FIG. 5(b), in the second exposure step, the fine lines that are not exposed in the first exposure step are partly exposed, thereby obtaining regions that are not exposed in the first and second exposure steps. The unexposed regions are used to form micropores in a subsequent step.

In a developing step (ST6 portion in FIG. 1), a developing method suitable for the negative photoresist material is employed. In the negative photoresist material, since cyclized rubber is photo-polymerized to form polymers, which are not soluble in a developing solution, the unexposed regions are dissolved in the developing solution containing, for example, xylenes and the developing solution are then removed with butylacetate rinse. In the same way as the first exemplary embodiment, post-baking and the removal of the photoresist material are performed. After the development, the photosensitive material layer 13 has the pattern shown in FIG. 4.

An etching step (ST7 portion in FIG. 1) is almost the same as that of the first exemplary embodiment except for that an etching method suitable for the photoresist material is employed.

The micropores formed according to the above procedure can be used to form crystal nuclei used to manufacture semiconductor devices, as described in exemplary embodiment 4. The method of forming the micropores according to this exemplary embodiment can be used in various industrial fields in which micropores are used.

As described above, according to the second exemplary embodiment, the micropores can be formed by an off-axis holographic exposure process using the negative photoresist material. This technique is very important one among basic microprocessing techniques in the field of nano-technology.

<Third Exemplary Embodiment>

A third exemplary embodiment provides another method of forming micropores. In this method, regions to form the micropores are confined within a specific area, where the regions are formed by any one of the methods of the first and second exemplary embodiments.

Regardless of whether a positive or negative photosensitive material is used, this method includes a third exposure step after a second exposure step.

When a positive photosensitive material is used in the same manner as that in the first exemplary embodiment, the intensity of a first diffracted beam used in a first exposure step (ST2 portion in FIG. 1) and a second diffracted beam used in a second exposure step (ST3 portion in FIG. 1) is different from that in the first exemplary embodiment. In the first exemplary embodiment, the first and second diffracted beams each have intensity that is not sufficient to cause a photochemical reaction in the photosensitive material and the total intensity of the first and second diffracted beams is sufficient to cause the photochemical reaction in the photosensitive material. In contrast, the third exemplary embodiment further includes a third exposure step. In this exemplary embodiment, the total intensity of the first and second diffracted beams is not sufficient to cause the photochemical reaction in the photosensitive material, and the total intensity of the first, second, and third diffracted beams is sufficient to cause such a reaction.

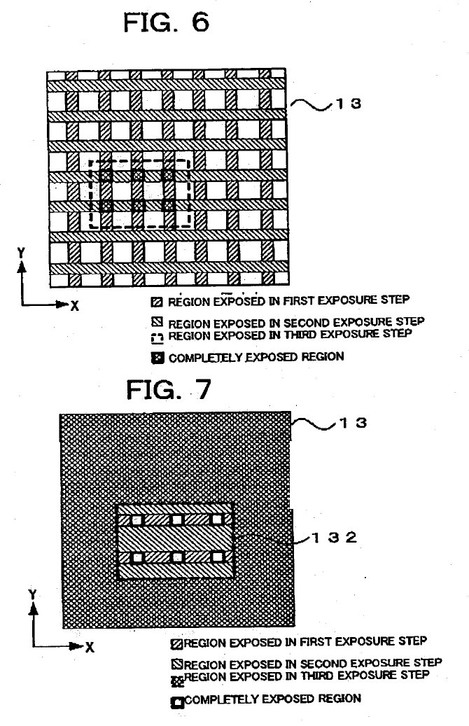

The third exposure step is arranged after the second exposure step. In the third exposure step, regions in which the micropores are not formed are masked and other regions to form the micropores are exposed in the third exposure step. Only in the regions exposed in the first, second, and third exposure steps, complete exposure is achieved. Referring to FIG. 6, the area surrounded by the broken line includes the regions exposed in the third exposure step. Only in these regions in the area (area surrounded by the solid line), complete exposure is achieved.

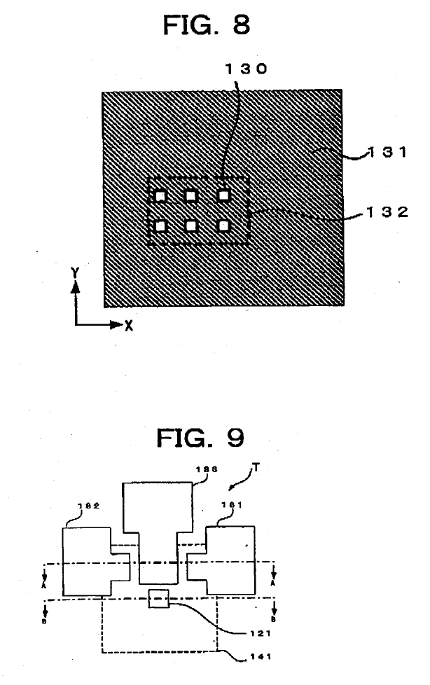

After the third exposure step, the development and the etching are performed in the same manner as that in the first embodiment. FIG. 8 is a plan view showing a developed photosensitive material layer 13 formed by the method of this embodiment. As shown in FIG. 8, windows 130 are disposed in a micropore-forming area 132. Therefore, micropores 121 formed in an etching step are confined within this area.

On the other hand, when a negative photosensitive material is used in the same manner as that in the second exemplary embodiment, the intensity of a first diffracted beam used in a first exposure step (ST2 portion in FIG. 1) and a second diffracted beam used in a second exposure step (ST3 portion in FIG. 1) is the same as that in the second exemplary embodiment. In each of the first and second exposure steps, the first and second diffracted beams independently have such intensity that complete exposure can be achieved in the photosensitive material.

In the third exposure step, regions to form the micropores 121 are masked and the other regions in which the micropores 121 are not formed are exposed. Before the third exposure step, there are unexposed regions, which are not exposed in the first and second exposure steps, in an area in which the micropores 121 are not formed. However, in the third exposure step, the entire area in which the micropores 121 are not formed is exposed. For example, as shown in FIG. 7, the micropore-forming area 132 is surrounded by the broken line, and the other area is exposed in the third exposure step. Thus, unexposed regions (regions surrounded by the solid lines) are only disposed in the micropore-forming area 132.

After the third exposure step, the development and the etching are performed in the same manner as that in the second exemplary embodiment. FIG. 8 is a plan view showing a developed photosensitive material layer 13 formed by the method of this exemplary embodiment. As shown in FIG. 8, windows 130 are disposed in a micropore-forming area 132. Therefore, micropores 121 formed in an etching step are confined within this area.

As described above, according to the third exemplary embodiment, micropores can be formed in a desired area, regardless of whether a positive or negative photosensitive material is used. Such an advantage is provided by the third exposure step in addition to the effects described in the first and second exemplary embodiments. Circuit devices can be selectively formed in a desired area by an off-axis holographic exposure process in which the resolution has anisotropy.

<Fourth Exemplary Embodiment>

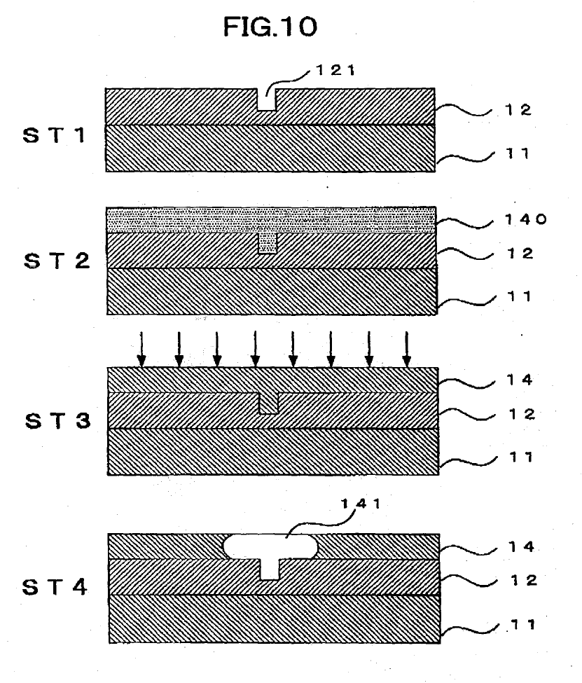

A fourth exemplary embodiment provides a method of manufacturing semiconductor devices using micropores formed by any one of the methods of the above first to third exemplary embodiments. FIGS. 9 and 10 are sectional views illustrating steps of the manufacturing method of this exemplary embodiment. In these sectional views, for the sake of simplicity, only the area surrounded by the broken line in the ST6 portion in FIG. 1 is shown, where the area contains one semiconductor device.

Each micropore 121 is formed in a silicon compound layer 12 by any one of the methods of the first to third exemplary embodiments (ST1 portion in FIG. 9).

Amorphous Silicon Layer-Forming Step (ST2 portion in FIG. 9)

An amorphous silicon layer 140 is formed on the silicon compound layer 12 and formed in the micropore 121 by a predetermined method, for example, an LPCVD method so as to have a predetermined thickness, for example, a thickness of 50 to 500 nm. In order to securely deposit high-purity silicon in the micropore 121, the LPCVD method is preferably used.

Polysilicon Layer-Forming Step (ST3 portion in FIG. 9)

The amorphous silicon layer 140 is then heat-treated such that polycrystals are formed by a solid-phase epitaxial method, thereby transforming the amorphous silicon layer 140 into a polysilicon layer 14. The conditions of the heat treatment are as follows: for example, a temperature of 600° C., a time of 24 to 48 hours, and a nitrogen atmosphere. During this heat treatment, solid-phase epitaxy occurs in the amorphous silicon layer 140 and therefore crystal grains in the amorphous silicon layer 140 grow to have a diameter of 0.5 to 2 μm. This crystal growth occurs in amorphous silicon in the micropores 121.

This step is not essential and may be omitted. That is, the amorphous silicon layer 140 may be transformed into a single-crystalline silicon layer in the next melting step.

Melting Step (ST4 portion in FIG. 9)

High energy is applied to the polysilicon layer 14 to cause the polysilicon layer 14 to melt. The energy source is, for example, a laser beam. In particular, for example, an XeCl pulse excimer laser beam having a wavelength of 308 nm and a pulse width of 30 nanosecond is used. In the laser irradiation, the energy density is 0.4 to 1.5 J/cm² depending on the thickness of the polysilicon layer 14, where the thickness is 50 to 500 nm in this exemplary embodiment. Thereby, part of the amorphous silicon layer is caused to melt while other portions of the amorphous silicon layer in the micropores are allowed to remain unmelted.

The reason that laser irradiation is preferably used to apply energy is as follows: the applied XeCl pulse excimer laser beam is mostly absorbed by the polysilicon layer 14 at the surface, because amorphous silicon and crystalline silicon have an absorption coefficient of 0.139 and 0.149 nm⁻¹, respectively, which are large values, for the XeCl pulse excimer laser beam having a wavelength of 308 nm.

After the laser irradiation, in the polysilicon layer 14, unmelted portions of silicon compound layer 12 in the micropores 121 function as crystal nuclei, thereby allowing the crystal growth to occur. In this exemplary embodiment, since the micropores 121 have a diameter that is smaller than or equal to the size of crystal grains that are formed by the heat treatment of the polysilicon layer 14, the crystal grains having substantially the same diameter are disposed on the corresponding micropores 121. When the molten silicon is solidified after the laser irradiation, each crystal grain functions as a crystal nuclear to allow crystal to grow. As a result, as shown in the ST4 portion in FIG. 10, substantially single-crystalline silicon sub-layers 141 are formed on the corresponding micropores 121 in the polysilicon layer 14.

According to this procedure, large-sized crystal grains, for example, 4-μm crystal grains, can be formed on the micropores 121. When the temperature of the sample is reduce to, for example, about 400° C., larger crystal grains, for example, 6-μm crystal grains, can be obtained.

Since the substantially single-crystalline silicon sub-layers 141 have a small number of internal defects, the following advantage that is one of the electronic properties of semiconductors can be obtained: the density of traps having an energy level near the bandgap center in the energy band profile is small. Furthermore, since the substantially single-crystalline silicon sub-layers 141 have no grain boundaries, the following advantage can be obtained: the energy barrier is extremely low when carriers, such as electrons and holes flow. When the substantially single-crystalline silicon sub-layers 141 are used for the active layers (source/drain regions and/or channel-forming regions) of thin-film transistors, the thin-film transistors have excellent characteristics, such as high mobility and a small current when turned off.

Semiconductor Device-Forming Step (FIG. 10)

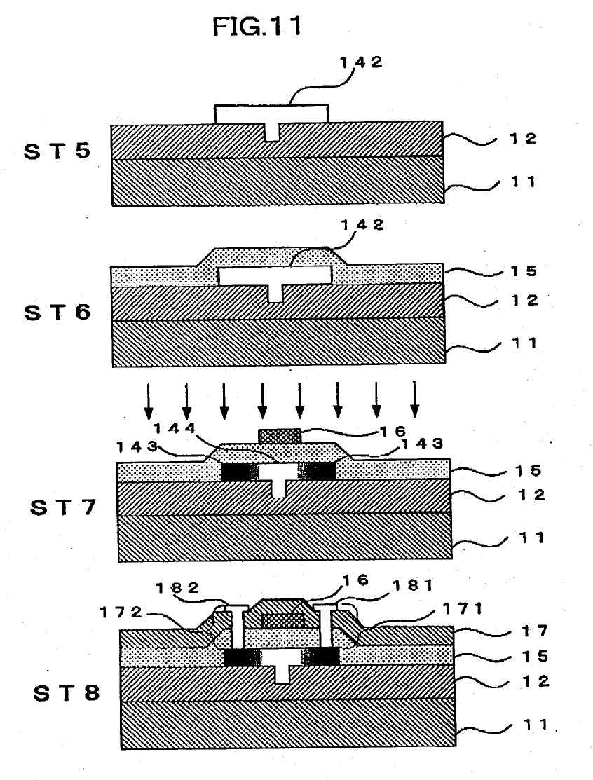

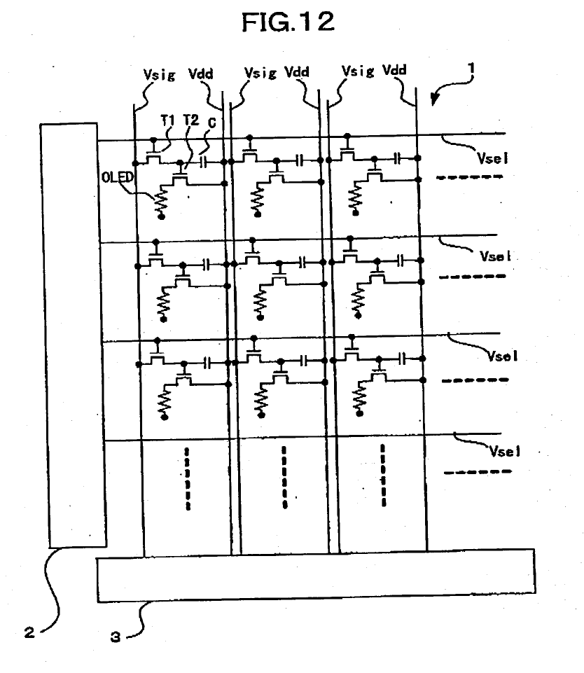

A method of manufacturing semiconductor devices, which are herein thin-film transistors, is described below with reference to FIGS. 9 and 11. FIG. 9 is a schematic plan view showing a thin-film transistor T and FIG. 11 is a schematic including sectional views illustrating steps of manufacturing the thin-film transistor T. Each sectional view in FIG. 11 corresponds to the sectional view taken along plane A-A of FIG. 9.

As shown in the ST5 portion of FIG. 11, each substantially single-crystalline silicon sub-layer 141 is patterned to form a semiconductor region (semiconductor layer) 142 for the thin-film transistor T. For example, an area of the substantially single-crystalline silicon sub-layer 141 except for each micropore 121 is used for a channel-forming region 144 for the thin-film transistor T.

As shown in the ST6 portion of FIG. 11, a first silicon oxide layer 15 is formed over a silicon compound layer 12 and the semiconductor region 142 by a known method, such as an electron cyclotron resonance PECVD (ECR-CVD) method, a parallel plate-type PECVD method, or an LPCVD method. The first silicon oxide layer 15 functions as a gate-insulating layer for the thin-film transistor T.

As shown in the ST7 portion of FIG. 11, a metal thin-film including a known gate metal, such as tantalum or aluminum, is formed by a sputtering method. The metal thin-film is then patterned to form a gate electrode 16.

Impurity ions functioning as donors or acceptors are implanted into the first silicon oxide layer 15 using the gate electrode 16 functioning as a mask to form a source/drain region 143 and a channel-forming region 144 in such a manner that the source/drain region 143 and the channel-forming region 144 are self-aligned with respect to the gate electrode 16. For example, when NMOS transistors are fabricated, phosphorus (P), which is an impurity, is implanted into an area for forming the source/drain region 143 such that the area has an impurity concentration of, for example, 1×10¹⁶ cm⁻².

Appropriate energy is then applied to the resulting area. For example, the area is irradiated with an XeCl excimer laser beam at an energy density of about 200 to 400 mJ/cm², or heat-treated at 250 to 450° C. to activate the impurity ions.

As shown in the ST8 portion of FIG. 11, a second silicon oxide layer 17 having a thickness of about 500 nm is formed over the first silicon oxide layer 15 and the gate electrode 16 by a known method, such as a PECVD method.

First and second contact holes 171 and 172, respectively, extending through the first silicon oxide layer 15 and the second silicon oxide layer 17 to the source/drain region 143 are formed. Aluminum is deposited on the walls of the first and second contact holes 171 and 172 and on the peripheries thereof to form first and second source/drain electrodes 181 and 182, respectively, by, for example, a sputtering method. In the same way as the above, another contact hole, which is not shown, extending to the gate electrode 16 is formed in the second silicon oxide layer 17 to form a terminal electrode 183 for the gate electrode 16, as shown in FIG. 11. According to the above procedure, the thin-film transistor T including the single-crystalline silicon sub-layer 141 having a small number of crystal defects is completed.

Thin-film transistors manufactured according to the above procedure include semiconductor layers including substantially single-crystalline silicon. Thus, the channel-forming regions of the thin-film transistors have a small number of grain boundaries and crystal defects that function as barriers when carriers flow.

<Fifth Exemplary Embodiment>

A fifth exemplary embodiment provides a display unit and an electronic device including a semiconductor device manufactured by a method of any one of the above embodiments.

FIG. 12 is a schematic circuit diagram of a display unit 1 according to this exemplary embodiment. The display unit 1 of this exemplary embodiment includes display regions and first and second driver regions 2 and 3. Each display region includes the following components: an emissive layer OLED to emit light in a electroluminescent manner, a capacitor C to store a current to drive the emissive layer, and first and second thin-film transistors T1 and T2, which are semiconductor devices manufactured by a manufacturing method of the present invention. The first driver region 2 has selection-signal lines Vsel connected to the corresponding display regions. The second driver region 3 has signal lines Vsig and source lines Vdd connected to the corresponding display regions. A program of supplying a current to each display region is performed by controlling the selection-signal lines Vsel and the signal lines Vsig to allow the emissive layers OLED to emit light.

The above driving circuit is an exemplary circuit including electroluminescence devices functioning as emissive elements, and other various circuits can be used. Another circuit including liquid crystal display devices functioning as emissive elements can be used.

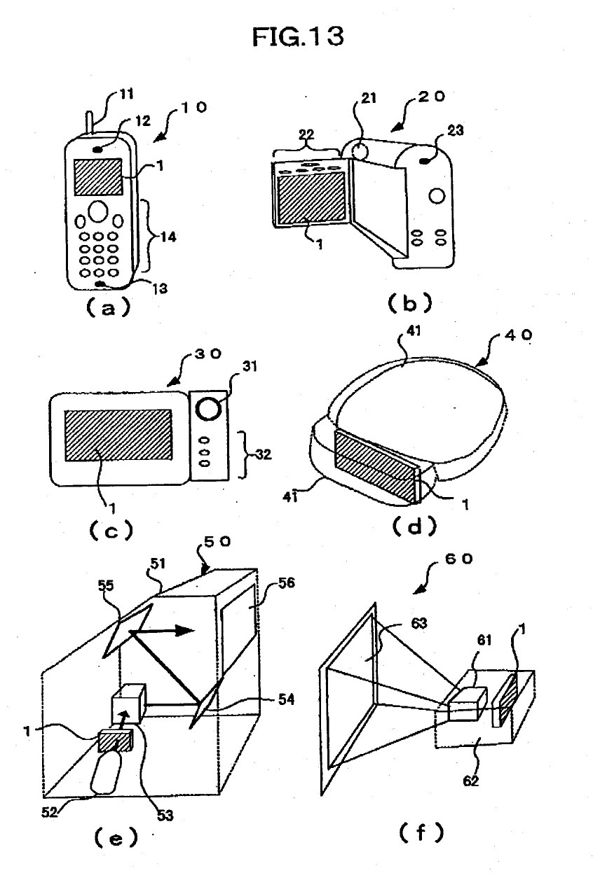

The display unit 1 of this exemplary embodiment can be used for various exemplary electronic devices. Such exemplary electronic devices including the display unit 1 are shown in FIGS. 13(a)-13(f).

FIG. 13(a) shows the application of the display unit 1 to a mobile phone. The mobile phone 10 includes an antenna 11, an audio output device 12, an audio input device 13, an operating device 14, and the display unit 1 of the present invention. As described above, the display unit 1 of the present invention can be used as a display device for mobile phones.

FIG. 13(b) shows the application of the display unit 1 to a video camera. The video camera 20 includes an image-receiving device 22, an operating device 21, an audio input device 23, and the display unit 1 of the present invention. As described above, the display unit 1 of the present invention can be used as finders and a display device for video cameras.

FIG. 13(c) shows the application of the display unit 1 to a personal computer. The personal computer 30 includes a camera 31, an operating device 32, and the display unit 1 of the present invention. As described above, the display unit 1 of the present invention can be used as a display device for personal computers.

FIG. 13(d) shows the application of the display unit 1 to a head-mounted display. The head-mounted display 40 includes a belt 41, an optical system-storing device 42, and the display unit 1 of the present invention. As described above, the display unit 1 of the present invention can be used as a display device for head-mounted displays.

FIG. 13(e) shows the application of the display unit 1 to a rear-type projector. The rear-type projector 50 includes a casing 51, a light source 52, an optical synthesizing system 73, first and second mirrors 74 and 75, a screen 76, and the display unit 1 of the present invention. As described above, the display unit 1 of the present invention can be used as image sources for rear-type projectors.

FIG. 13(f) shows the application of the display unit 1 to a front-type projector. The front-type projector 60 includes a casing 62, an optical system 61, and the display unit 1 of the present invention, thereby displaying an image on a screen 83. As described above, the display unit 1 of the present invention can be used as image sources for front-type projectors.

The display unit 1 of the present invention is not limited to the above applications and can be used for various electronic devices that need to have an active matrix display. Such electronic devices include fax machines having a display function, finders for digital cameras, mobile TVs, DSPs, PDAs, electronic notebooks, electronic billboards, and commercial displays, for example.

[Advantages]

As described above, according to the present invention, micropores can be formed by an off-axis holographic exposure process using a pattern having high resolution and a positive or negative photosensitive material. Thus, this technique is very important among basic microprocessing techniques in the field of nano-technology.

According to the present invention, the micropores can be formed by the above method to allow crystals to grow using the micropores to form single-crystalline semiconductors having high quality, thereby obtaining high-performance semiconductor devices. For example, when thin-film transistors functioning as semiconductor devices are used, the following excellent properties can be obtained: a small current while turned off, a sharp threshold property, and high mobility.

What is claimed is:

1. A method of forming micropores in a substrate, comprising:
forming a photosensitive material layer on the substrate using a photosensitive material;
applying a reconstruction beam on a holographic mask, which has a pattern that is formed by an off-axis holographic exposure process and has high resolution in a predetermined direction, to allow the holographic mask to emit a first diffracted beam, and then exposing the photosensitive material layer to the first diffracted beam;
causing the holographic mask to rotate at a predetermined angle with respect to the substrate or causing the substrate to rotate at a predetermined angle with respect to the holographic mask, applying the reconstruction beam to the holographic mask to emit a second diffracted beam, and then exposing the photosensitive material layer to the second diffracted beam;
removing unnecessary portions from the photosensitive material layer by developing the photosensitive material layer; and
forming micropores in the substrate by etching the substrate using the resulting photosensitive material layer on the substrate.

2. A method of forming micropores in a substrate, comprising:
forming a photosensitive material layer on the substrate using a positive photosensitive material;
arranging the substrate and a holographic mask, which has a pattern that is formed by an off-axis holographic exposure process and has high resolution in a predetermined direction, such that the holographic mask face is parallel to the substrate face and the reference direction of the holographic mask face forms a predetermined angle with respect to the reference direction of the substrate face, applying a reconstruction beam on the holographic mask to allow the holographic mask to emit a first diffracted beam, and then exposing the photosensitive material layer to the first diffracted beam;
varying the angle formed by the reference direction of the holographic mask face and the reference direction of the substrate face, applying the reconstruction beam on the holographic mask to allow the holographic mask to emit a second diffracted beam, and then exposing the photosensitive material layer to the second diffracted beam;
removing unnecessary portions from the photosensitive material layer by developing the photosensitive material layer; and
forming micropores in the substrate by etching the substrate using the resulting photosensitive material layer on the substrate;
the intensity of the first diffracted beam and the intensity of the second diffracted beam being lower than intensity that is sufficient to cause a photochemical reaction in the photosensitive material, and the total intensity of the first and second diffracted beams being higher than the intensity that is sufficient to cause a photochemical reaction in the photosensitive material.

3. The method of forming micropores according to claim 2, further comprising exposing a region on the substrate, the region being used to form the micropores.

4. The method of forming micropores according to claim 2, the holographic mask having a pattern formed by an off-axis holographic exposure process by applying a beam on an original reticle having a striped pattern including one or more lines arranged in such a direction that high resolution is obtained when off-axis holographic exposure is performed.

5. The method of forming micropores according to claim 4, the holographic mask having a striped pattern that has a line width that is substantially equal to the desired diameter of the micropores.

6. A method of forming micropores in a substrate, comprising:
forming a photosensitive material layer on the substrate using a negative photosensitive material;
arranging the substrate and a holographic mask, which has a pattern that is formed by an off-axis holographic exposure process and has high resolution in a predetermined direction, such that the holographic mask face is parallel to the substrate face and the reference direction of the holographic mask face forms a predetermined angle with respect to the reference direction of the substrate face, applying a reconstruction beam on the holographic mask to allow the holographic mask to emit a first diffracted beam, and then exposing the photosensitive material layer to the first diffracted beam;
varying the angle formed by the reference direction of the holographic mask face and the reference direction of the substrate face, applying the reconstruction beam on the holographic mask to allow the holographic mask to emit a second diffracted beam, and then exposing the photosensitive material layer to the second diffracted beam;
removing unnecessary portions from the photosensitive material layer by developing the photosensitive material layer; and
forming micropores in the substrate by etching the substrate using the resulting photosensitive material layer on the substrate;
the first and second diffracted beams independently having intensity that is sufficient to cause a photochemical reaction in the photosensitive material.

7. The method of forming micropores according to claim 6, further comprising exposing a region on the substrate, the region not being used to form the micropores.

8. The method of forming micropores according to claim 6, the holographic mask having a pattern formed by an off-axis holographic exposure process by applying a beam on an original reticle that has a striped pattern including one or more lines arranged in such a direction that high resolution is obtained when off-axis holographic exposure is performed.

9. The method of forming micropores according to claim 8, the holographic mask having a striped pattern that has a line pitch that is substantially equal to the desired diameter of the micropores.

10. A method of manufacturing semiconductor devices, comprising:
forming micropores in a region of the substrate by the method of forming micropores according to claim 1, the region being used to form semiconductor devices using a silicon compound;
forming an amorphous silicon layer on the substrate having the micropores so as to have a predetermined thickness;
transforming the amorphous silicon layer into a polysilicon layer by a solid-phase growth method using heat treatment;
applying a laser beam on the amorphous silicon layer to cause part of the amorphous silicon layer to melt while other portions of the amorphous silicon layer in the micropores are allowed to remain unmelted, and then allowing crystalline nuclei, which have formed in the unmelted portions of the amorphous silicon layer in the micropores, to grow to form substantially single-crystalline silicon sub-layers in the amorphous silicon layer, the sub-layers each lying on the corresponding micropores; and
forming semiconductor devices including the substantially single-crystalline silicon sub-layers functioning as semiconductor sub-layers.

11. The method of manufacturing semiconductor devices according to claim 10, the semiconductor devices including parts of the substantially single-crystalline silicon sub-layers except for regions of the substantially single-crystalline silicon sub-layers in the micropores.

12. The method of manufacturing semiconductor devices according to claim 10, the micropores having a diameter that is smaller than or equal to that of polysilicon grains formed by the solid-phase growth method using the heat treatment.

13. The method of manufacturing semiconductor devices according to claim 10, the substrate having a multilayer structure including a silicon oxide layer and a silicon nitride layer, and the silicon oxide layer being disposed at a position close to the amorphous silicon layer.

14. A semiconductor device manufactured by the method of forming semiconductor devices according to claim 10.

15. A display unit, comprising:
the semiconductor device according to claim 14.

16. An electronic device, comprising:
the semiconductor device according to claim 14.
